(19) United States
(12) Patent Application Publication
(10) Pub. No.: US 2025/0037971 A1
(43) Pub. Date: Jan. 30, 2025

(54) PLASMA PROCESSING DEVICE

(71) Applicant: ADVANCED MICRO-FABRICATION EQUIPMENT INC. CHINA, Shanghai (CN)

(72) Inventors: Tuqiang NI, Shanghai (CN); Zhihao WANG, Shanghai (CN); Kailin WANG, Shanghai (CN)

(21) Appl. No.: 18/713,606

(22) PCT Filed: Sep. 19, 2022
(86) PCT No.: PCT/CN2022/119602

§ 371 Date: May 24, 2024

(30) Foreign Application Priority Data
Jan. 27, 2022 (CN) 202210104678.9

(51) Int. Cl. H01J 37/32

(52) U.S. Cl. CPC H01J 37/32082; H01J 37/32513; H01J 37/32568; H01J 37/32577; H01J 37/32642

(57) ABSTRACT

A plasma processing device includes: a vacuum processing chamber internally provided with a movable lower electrode assembly; a movable grounding ring arranged at a bottom of the movable lower electrode assembly; a fixed grounding ring arranged below the movable grounding ring; a retractable sealing assembly arranged between the movable grounding ring and the fixed grounding ring; a conductive connector used for forming a radio frequency path between the movable grounding ring and the fixed grounding ring, where a distance between an outer wall of the retractable sealing assembly and a central axis of the vacuum processing chamber is less than an outer diameter of the movable grounding ring; and a match with a radio frequency transmitting end and a radio frequency receiving end of a radio frequency circuit. The plasma processing device has the advantages that the device utilizes the conductive connector for sharing the radio frequency current bearing pressure of the retractable sealing assembly, and meanwhile, the retractable sealing assembly is far away from a vertical part of the fixed grounding ring, thereby weakening horizontal-direction radio frequency coupling of the fixed grounding ring to the retractable sealing assembly, and even when the retractable sealing assembly is stretched or compressed, the radio frequency circuit cannot be greatly influenced.

### TECHNICAL FIELD

The present disclosure relates to the field of semiconductor apparatuses, and more particularly relates to a plasma processing device.

### BACKGROUND ART

Mass micro processing is required in the semiconductor chip production process, and common micro processing technologies include manners such as plasma etching, physical vapor deposition and chemical vapor deposition. Plasma auxiliary processes are commonly adopted during micro processing and manufacturing, which are commonly performed in a vacuum processing chamber. A working principle of a vacuum processing chamber commonly refers to: the vacuum processing chamber is inflated with a proper amount of reactive gas such as etching agent or deposition source gas, and then radio frequency energy is input into the vacuum processing chamber so as to activate the reactive gas to ignite or maintain plasma, thereby processing a semiconductor substrate.

However, along with the increasingly reduced feature size of semiconductor devices and the increasingly improved device integration level, higher and higher requirements are proposed for micro processing. To meet constantly improved processing requirements, an upper electrode assembly and a lower electrode assembly may have different electrode plate gaps, so as to finish different etching steps. Along with electrode plate gap adjustment, a complex radio frequency environment in the vacuum processing chamber fluctuates accordingly. For example, the lower electrode assembly can move up and down so as to adjust the electrode plate gap, which serves as a part of a radio frequency circuit. When the lower electrode assembly moves up and down, a distance between the lower electrode assembly and a chamber body bottom wall similarly serving as a part of the radio frequency circuit also changes, which is likely to cause instability of radio frequency signals, and then causes instability of the radio frequency environment in the vacuum processing chamber. How to combine the adjustable electrode plate gap with stability of the radio frequency circuit is an urgent problem to be solved.

It is to be explained that the description here merely provides the background art related to the present disclosure, but does not necessarily constitute the prior art.

### SUMMARY OF THE INVENTION

An objective of the present disclosure is to provide a plasma processing device. The device combines a movable grounding ring, a fixed grounding ring, a retractable sealing assembly, a conductive connector, etc., which eliminates unexpected radio frequency in a radio frequency circuit, which coupled to the retractable sealing assembly. The conductive connector shares the radio frequency current bearing pressure of the retractable sealing assembly, and meanwhile, the retractable sealing assembly is far away from a vertical part of the fixed grounding ring, thereby weakening horizontal-direction radio frequency coupling of the vertical part of the fixed grounding ring to the retractable sealing assembly, and even when the movable lower electrode assembly moves up and down to drive the retractable sealing assembly to be stretched and compressed, the radio frequency circuit cannot be greatly influenced, and thus, the device can still be kept at a stable etching rate under different electrode plate gaps.

In order to achieve the above objective, the present disclosure is implemented by the following technical schemes:

A plasma processing device includes:
a vacuum processing chamber internally provided with a movable lower electrode assembly:
a movable grounding ring arranged at a bottom of the movable lower electrode assembly in an encircling manner:
a fixed grounding ring arranged below the movable grounding ring in an encircling manner and in contact with a bottom of the vacuum processing chamber:
a retractable sealing assembly arranged between the movable grounding ring and the fixed grounding ring in an encircling manner:
a conductive connector used for forming a radio frequency path between the movable grounding ring and the fixed grounding ring, where a distance between an outer wall of the retractable sealing assembly and a central axis of the vacuum processing chamber is less than an outer diameter of the movable grounding ring; and
a match fixed to the bottom of the vacuum processing chamber, where the radio frequency has a radio frequency transmitting end and a radio frequency receiving end of a radio frequency circuit.

Optionally, the conductive connector is electrically connected to the movable grounding ring and the fixed grounding ring.

Optionally, the conductive connector is arranged on the side of the retractable sealing assembly, which away from an inner side wall of the vacuum processing chamber.

Optionally, the plasma processing device further includes an upper electrode assembly opposite to the movable lower electrode assembly; and
a RF rod with two ends connected to the movable lower electrode assembly and the radio frequency transmitting end of the match respectively;
the vacuum processing chamber includes a processing chamber side wall and a processing chamber bottom wall; and the retractable sealing assembly is electrically connected to the movable grounding ring and the fixed grounding ring; and
according to the radio frequency path of the plasma processing device, a radio frequency current output by the radio frequency transmitting end of the match enters the movable lower electrode assembly through the RF rod, enters the upper electrode assembly through plasma between the upper electrode assembly and the movable lower electrode assembly, and then is transmitted to the radio frequency receiving end of the match sequentially through the processing chamber side wall, an inner side of the fixed grounding ring, an outer side of the retractable sealing assembly, an outer side of the movable grounding ring, an inner side of the movable grounding ring, a bottom of the movable grounding ring, an inner side of the conductive connector, the inner side of the fixed grounding ring and the processing chamber bottom wall.

Optionally, a length of the conductive connector is greater than or equal to a maximum height of the retractable sealing assembly.

Optionally, the conductivity of the conductive connector is greater than that of the retractable sealing assembly.

Optionally, the conductive connector is a conductor or flexible metal sheet.

Optionally, the conductor is a copper conductor, and the flexible metal sheet is flexible copper sheet.

Optionally, the flexible metal sheet is bent metal sheet with the bending direction towards a chamber body center of the vacuum processing chamber.

Optionally, the plurality of conductive connectors are arranged and symmetrically arranged relative to a central axis of the movable lower electrode assembly.

Optionally, a prepared material of the retractable sealing assembly is stainless steel.

Optionally, the retractable sealing assembly includes a bellows.

Optionally, a top and a bottom of the conductive connector are electrically connected to a top and a bottom of the retractable sealing assembly respectively.

Optionally, end parts of the retractable sealing assembly are fixed to the movable grounding ring and the fixed grounding ring through flange assemblies.

Optionally, positions where the flange assemblies are in contact with the movable grounding ring or the fixed grounding ring are provided with a plurality of sealing members.

Optionally, the conductive connector is arranged on the side of the retractable sealing assembly, which close to an inner side wall of the vacuum processing chamber, and the conductive connector is prepared by materials not reacting with process gas or byproducts in the vacuum processing chamber thereof.

Optionally, there is one or more matches, and the plurality of matches are different in radio frequency and power.

Compared with the prior art, the present disclosure has the following advantages:
the plasma processing device according to the present disclosure combines the movable grounding ring, the fixed grounding ring, the retractable sealing assembly with the conductive connector, etc., the conductive connector shares the radio frequency current bearing pressure of the retractable sealing assembly, and meanwhile, the retractable sealing assembly is far away from the vertical part of the fixed grounding ring, thereby weakening the horizontal-direction radio frequency coupling of the vertical part of the fixed grounding ring to the retractable sealing assembly, and even when the retractable sealing assembly is stretched or compressed, the radio frequency circuit cannot be greatly influenced.

Further, the retractable sealing assembly in the device is electrically connected to the movable grounding ring and the fixed grounding ring, so that the vertical-direction radio frequency coupling caused by the movable grounding ring and the fixed grounding ring to the retractable sealing assembly is eliminated; and meanwhile, the retractable sealing assembly and the conductive connector jointly share the radio frequency current, and thus, the radio frequency pressure required to be borne by the retractable sealing assembly and the losses of the retractable sealing assembly are reduced, and the service life of the retractable sealing assembly is prolonged.

Further, the top and the bottom of the conductive connector in the device are electrically connected to the top and the bottom of the retractable sealing assembly respectively, and there is no distance difference therebetween in the horizontal direction. When the radio frequency current is transferred, no matter how the retractable sealing assembly is stretched or compressed, the impedance difference between the retractable sealing assembly and the conductive connector is very small, and no additional radio frequency circuit is generated therebetween, thereby further guaranteeing the stability of the integral radio frequency circuit, contributing to improving the stability of the etching rate, and then, guaranteeing the wafer production yield.

### BRIEF DESCRIPTION OF THE DRAWINGS

FIG. 1 is a schematic diagram of a plasma processing device according to the present disclosure;

FIG. 2 is a schematic diagram of another plasma processing device according to the present disclosure; and

FIG. 3 is a schematic diagram of further plasma processing device according to the present disclosure.

### DETAILED DESCRIPTION OF THE INVENTION

To make objectives, technical schemes and advantages of embodiments of the present disclosure more clear, the technical schemes in the embodiments of the present disclosure are clearly and integrally described in combination with drawings in the embodiments of the present disclosure as below, and it is apparent that the described embodiments are only a part rather all of embodiments. Based on the embodiments of the present disclosure, all other embodiments obtained by those of ordinary skill in the art without contributing creative labor shall fall within the scope of protection of the present disclosure.

It is to be explained that herein, terms “comprise”, “include”, “have” or any other transformations thereof are intended to cover non-exclusive inclusion, and thus a process, a method, an object or a terminal apparatus including a series of elements not only includes those elements but also includes other elements not clearly listed, or further includes inherent elements for the process, the method, the object or the terminal apparatus. Elements limited by a statement “comprising . . . ” or “including . . . ”, without more limitations, indicate that additional elements may exist in the process, the method, the object or the terminal apparatus including the elements.

It is to be explained that the drawings adopt a simplified form and use an inaccurate rate, which are only intended to conveniently and clearly assist in describing the purposes of the embodiment of the present disclosure.

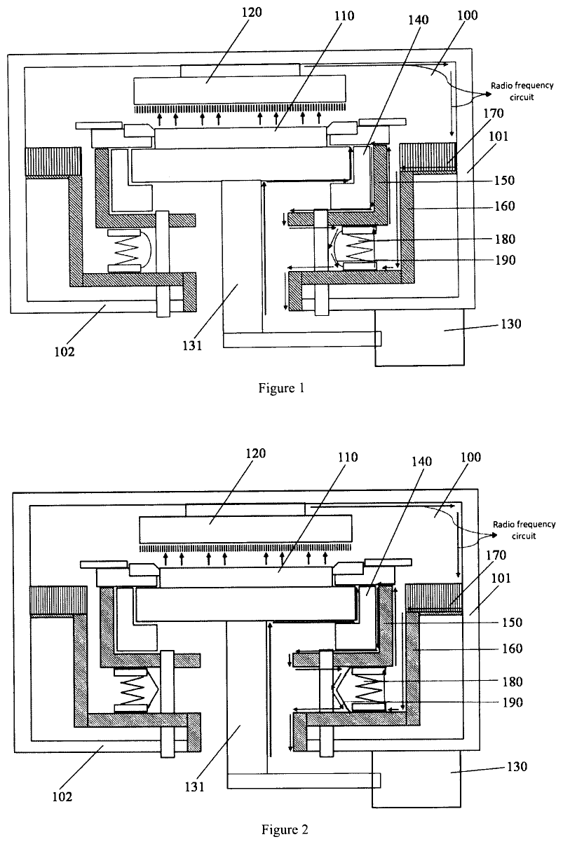

FIG. 1 illustrates a plasma processing device according to the present disclosure. The plasma processing device includes a vacuum processing chamber 100 surrounded by a processing chamber body and a chamber body end cover. The processing chamber body 100 includes a processing chamber side wall 101 and a processing chamber bottom wall 102, where a wafer transfer port (not shown in the figure) is provided with the processing chamber side wall 101 and used to realize transfer a wafer inside and outside the vacuum processing chamber 100. The vacuum processing chamber 100 internally includes a movable lower electrode assembly 110 arranged at an inner bottom of the vacuum processing chamber 100, and the movable lower electrode assembly 110 is provided with a bearing plane, and a to-be-processed wafer transferred into the vacuum processing chamber 100 is placed on the bearing plane. The vacuum processing chamber 100 internally further includes an upper electrode assembly 120 opposite to the movable lower electrode assembly 110. The upper electrode assembly 120 includes a showerhead, and the showerhead is connected to a gas supply device. Process gas in the gas supply device enters the vacuum processing chamber 100 through the showerhead, thereby facilitating the technological process in a reaction region between the movable lower electrode assembly 110 and the upper electrode assembly 120. At least one radio frequency power supply applies, by a match 130, radio frequency power to the movable lower electrode assembly 110 or the upper electrode assembly 120 so as to disintegrate the process gas into plasma, and accordingly, a plasma environment is formed between the upper electrode assembly 120 and the movable lower electrode assembly 110 and contains a large quantity of electrons, ions, excited-state atoms, molecules, free radicals and other active particles, and the active particles may perform multiple physical and/or chemical reactions with a surface of the to-be-processed wafer, so that the shape of the to-be-processed wafer changes, thereby finishing etching treatment on the to-be-processed wafer.

The match 130 is provided with a radio frequency transmitting end and a radio frequency receiving end of the radio frequency circuit, where the radio frequency transmitting end is configured to output a radio frequency current transferred by the radio frequency power supply, and the radio frequency receiving end is configured to receive the returned radio frequency current. In the embodiment, the match 130 is fixed to a bottom of the vacuum processing chamber 100 with the radio frequency transmitting end electrically connected to the movable lower electrode assembly 110 through a RF rod 131. The match 130 adjusts impedance according to different radio frequencies applied by the radio frequency power supply so that the radio frequency power can be coupled to the movable lower electrode assembly 110 to the maximum degree. Because the match 130 is fixed to the bottom of the vacuum processing chamber 100, when the movable lower electrode assembly 110 moves up and down along with the RF rod 131, the match 130 cannot move accordingly, which avoids bad influences of the instable radio frequency power.

Of course, the setting of the match 130 is not limited thereto. There may be one or more matches 130, and the plurality of matches 130 are different in radio frequency and power. In some embodiments, the movable lower electrode assembly 110 may be connected to the one or more matches 130, such as 2 matches 130. In the embodiment where the plurality of matches 130 are connected, each match 130 can provide radio frequency and power different from those of the other matches 130 so as to satisfy requirements of different processing technologies, and in these embodiments, the upper electrode assembly 120 may be grounded. In some other embodiments, the movable lower electrode assembly 110 may be connected to one match 130, and the upper electrode assembly 120 may be connected to the other match 130, and the two matches 130 can provide different radio frequencies and powers so as to satisfy process requirements.

In the embodiment, the plasma processing device further includes an insulation ring 140 and a movable grounding ring 150. The insulation ring 140 encircles the movable lower electrode assembly 110 and is fixedly connected to the movable lower electrode assembly 110. The movable grounding ring 150 encircles a bottom of the movable lower electrode assembly 110, and specifically, the movable grounding ring 150 is fixedly arranged on an outer side of the insulation ring 140. The insulation ring 140 is made of insulation materials, such as ceramic materials, so as to electrically isolate the movable lower electrode assembly 110 and the movable grounding ring 150. The movable grounding ring 150 is made of conductive materials, which serves as a part of a radio frequency return path.

Further, the vacuum processing chamber 100 is internally further provided with a fixed grounding ring 160. The fixed grounding ring 160 is arranged below the movable grounding ring 150 in an encircling manner and in contact with the bottom of the vacuum processing chamber 100, and the fixed grounding ring 160 is made of conductive materials, which similarly serves as a part of the radio frequency return path. A gap is formed between the fixed grounding ring 160 and the movable grounding ring 150, and the movable grounding ring 150 is used for shielding radio frequency interference between the movable lower electrode assembly 110 and the fixed grounding ring 160. A cavity is formed between the fixed grounding ring 160 and the processing chamber side wall 101 so as to form an exhaust cavity. A plasma confinement ring 170 is arranged above the cavity: The plasma confinement ring 170 confines the plasma to the reaction region between the upper electrode assembly 120 and the movable lower electrode assembly 110 so as to prevent the plasma from leaking into a non-reaction region, thereby avoiding damage to components in the non-reaction region. The plasma confinement ring 170 is of a ventilation structure, which can extinguish the surplus plasma in the vacuum processing chamber 100 and make waste gas enter the exhaust cavity to be exhausted out of the plasma processing device. It is to be understood that the exhaust cavity is connected to a vacuum pump so as to exhaust the waste gas out of the chamber.

In the embodiment, a retractable sealing assembly 180 is arranged in the gap between the movable grounding ring 150 and the fixed grounding ring 160 in an encircling manner so as to seal an upper surface of the movable lower electrode assembly 110 in a closed environment of the vacuum processing chamber 100. As shown in FIG. 1, a closed space at a lower part in the vacuum processing chamber 100 is enclosed by a side wall of the fixed grounding ring 160, an inner wall of the retractable scaling assembly 180 and a side wall of the movable grounding ring 150, so that the upper surface of the movable lower electrode assembly 110 is arranged in the processing chamber body while a lower surface of the movable lower electrode assembly 110 and the RF rod 131 are arranged outside the processing chamber body, and a vacuum environment is provided in the closed environment in the processing chamber body so as to perform an etching process.

During practical application, when the movable lower electrode assembly 110 moves up and down, the stretching and compression quantity of the retractable sealing assembly 180 changes accordingly. If the retractable sealing assembly 180 is respectively in insulating connection to the movable grounding ring 150 and the fixed grounding ring 160 so that the retractable scaling assembly 180 can isolate the radio frequency, the radio frequency current on the movable grounding ring 150 and the fixed grounding ring 160 can be transferred by other conductive components so as to form the radio frequency circuit, and the retractable sealing assembly 180 is arranged outside the radio frequency circuit. When the movable lower electrode assembly 110 descends to be closer to the processing chamber bottom wall 102, the fixed grounding ring 160 and the movable grounding ring 150 in the radio frequency circuit are likely to be coupled to form capacitance, part of the radio frequency is likely to jump to the retractable sealing assembly 180 to form vertical-direction coupling, and along with different distances between the fixed grounding ring 160 and the movable grounding ring 150, the amount of compression of the retractable sealing assembly 180 is different, accordingly, different capacitances and inductances are achieved, which causes poor impedance stability, as a result, integral radio frequency electric field stability is influenced, uncertain serial or parallel resonance is likely to be generated in the chamber body, and consequently, an etching rate is instable; and meanwhile, since the retractable scaling assembly 180 is close to a side surface of the fixed grounding ring 160 (a vertical part), there is still part of the radio frequency to be coupled to the retractable sealing assembly 180 in a horizontal direction from the vertical part of the fixed grounding ring 160 to form horizontal-direction coupling, which causes the instable radio frequency circuit. In the other aspect, if the retractable sealing assembly 180 is respectively electrically connected to the movable grounding ring 150 and the fixed grounding ring 160, the radio frequency current on the movable grounding ring 150 and the fixed grounding ring 160 can be transferred by the retractable scaling assembly 180 to become a part of the radio frequency circuit. When the movable lower electrode assembly 110 moves up and down, the stretching and compression quantity of the retractable scaling assembly 180 is different, which influences stability of a radio frequency electric field, and the excessive radio frequency current transferred by the retractable scaling assembly 180 is likely to cause losses of the retractable sealing assembly 180 and shorten the service life of the retractable scaling assembly 180.

For the above problems, the plasma processing device according to the present disclosure further includes a conductive connector 190, the conductive connector 190 is used for forming a radio frequency path between the movable grounding ring 150 and the fixed grounding ring 160, and a distance between an outer wall of the retractable sealing assembly 180 and a central axis of the chamber body is less than an outer diameter of the movable grounding ring 150, that is, the retractable sealing assembly 180 is away from the vertical part of the fixed grounding ring 160. Because the conductive connector 190 forms the radio frequency path between the movable grounding ring 150 and the fixed grounding ring 160 in the radio frequency circuit, the radio frequency current on the movable grounding ring 150 and the fixed grounding ring 160 can be transferred by the conductive connector 190, which can reduce the pressure of the retractable sealing assembly 180 bearing the radio frequency current, reduce the losses of the retractable sealing assembly 180 and prolong the service life of the retractable sealing assembly. Meanwhile, the outer wall of the retractable scaling assembly 180 is away from the vertical part of the fixed grounding ring 160, which can reduce coupling of the radio frequency on the vertical part of the fixed grounding ring 160 to the retractable sealing assembly 180 in the horizontal direction, reduce the pressure of the retractable sealing assembly 180 bearing the radio frequency current, reduce the radio frequency interference applied to the retractable scaling assembly 180, maintain the stability of the radio frequency field in the vacuum processing chamber 100 and improve stability of the etching rate. Theoretically, when a longitudinal space between the movable grounding ring 150 and the fixed grounding ring 160 is large enough, the longer the distance between the retractable sealing assembly 180 and the vertical part of the fixed grounding ring 160 is, the better the effect will be (do not influence placement and actions of the rest of components), so as to prevent the retractable sealing assembly 180 from being subjected to radio frequency interference, in the horizontal direction, of the vertical part of the fixed grounding ring 160.

In the embodiment, the retractable sealing assembly 180 is electrically connected to the movable grounding ring 150 and the fixed grounding ring 160, the radio frequency current on the movable grounding ring 150 or the fixed grounding ring 160 is transferred by the retractable scaling assembly 180, and the retractable sealing assembly 180 cannot generate vertical-direction radio frequency coupling, which reduces uncertainness of radio frequency changes; and meanwhile, due to the conductive connector 190, there will be not too much radio frequency current on the retractable scaling assembly 180, and thus, stretching and compression of the retractable sealing assembly 180 cannot greatly interfere with the radio frequency circuit, which facilitates maintenance of the stability of the integral radio frequency electric field, and then guarantees the stability of the wafer etching rate. Of course, the retractable sealing assembly 180 may not be electrically connected to the movable grounding ring 150 and the fixed grounding ring 160, the radio frequency current on the movable grounding ring 150 and the fixed grounding ring 160 is transferred by the conductive connector 190, the retractable sealing assembly 180 is far away from the vertical part of the fixed grounding ring 160, and thus, influences of horizontal coupling radio frequency generated by the vertical part of the fixed grounding ring 160 on the retractable sealing assembly 180 are weak, which facilitates protection of the retractable sealing assembly 180 and prolongs the service life of the retractable sealing assembly 180.

As shown in FIG. 1, in the embodiment, the conductive connector 190 is arranged on the side of the retractable sealing assembly 180, which away from the processing chamber side wall 101, that is, the conductive connector 190 is located outside a sealing environment of the vacuum processing chamber 100. In the technological process, the process gas can be disintegrated in a sealing space of the vacuum processing chamber 100 so as to form a plasma field to facilitate the etching process. The conductive connector 190 outside the sealing environment cannot be disturbed by the plasma, is long in service life and low in loss, and meanwhile shares the radio frequency current for the retractable sealing assembly 180, which reduces the radio frequency pressure of the retractable sealing assembly 180. At the time, according to the radio frequency path of the plasma processing device, the radio frequency power output by the radio frequency power supply is transferred to the match 130, the radio frequency current output by the radio frequency transmitting end of the match 130 enters the movable lower electrode assembly 110 through the RF rod 131, enters the upper electrode assembly 120 through plasma between the upper electrode assembly 120 and the movable lower electrode assembly 110, and then is transmitted to the radio frequency receiving end of the match 130 sequentially through the processing chamber side wall 101, an inner side of the fixed grounding ring 160, an outer side of the retractable sealing assembly 180, an outer side of the movable grounding ring 150, an inner side of the movable grounding ring 150, a bottom of the movable grounding ring 150, an inner side of the conductive connector 190, the inner side of the fixed grounding ring 160 and the processing chamber bottom wall 102.

It is to be explained that the conductive connector 190 is not limited to be arranged on the side of the retractable sealing assembly 180, which away from the processing chamber side wall 101. For example, in another embodiment, the conductive connector 190 is arranged on the side of the retractable sealing assembly 180, which close to the processing chamber side wall 101, that is, the conductive connector 190 is prepared by materials not reacting with the process gas and byproducts in the vacuum processing chamber 100 thereof. In the embodiment, the conductive connector 190 similarly has the function of sharing the radio frequency for the retractable sealing assembly 180, so as to reduce the radio frequency pressure of the retractable sealing assembly 180 and meanwhile guarantee the stability of the radio frequency circuit. At the time, according to the radio frequency path of the plasma processing device, the radio frequency power output by the radio frequency power supply arrives at the RF rod 131 through the radio frequency transmitting end of the match 130 so as to enter the movable lower electrode assembly 110, enters the upper electrode assembly 120 through the plasma between the upper electrode assembly 120 and the movable lower electrode assembly 110, and then is transmitted to the radio frequency receiving end of the match 130 sequentially through the processing chamber side wall 101, the inner side of the fixed grounding ring 160, an outer side of the conductive connector 190, the outer side of the movable grounding ring 150, the inner side of the movable grounding ring 150, the bottom of the movable grounding ring 150, the inner side of the retractable sealing assembly 180, the inner side of the fixed grounding ring 160 and the processing chamber bottom wall 102.

In further embodiment, conductive connectors 190 are respectively arranged on two sides of the retractable sealing assembly 180, and the conductive connectors 190 participate in the radio frequency circuit so as to make the radio frequency current on the retractable sealing assembly 180 as little as possible (possibly zero) to the maximum degree, thereby protecting the retractable sealing assembly 180, making the retractable sealing assembly 180 in a radio frequency shielding state, prolonging the service life of the retractable sealing assembly 180 and meanwhile weakening the influences of stretching and compression of the retractable sealing assembly 180 on the radio frequency field.

Optionally, the retractable sealing assembly 180 is prepared by stainless steel, and of course, may be prepared by any other material capable of realizing a corresponding retractable sealing function, which is not limited by the present disclosure. In the embodiment, the retractable sealing assembly 180 includes a bellows prepared by a stainless steel material, which has high mechanical toughness and a large retractable stroke, is not prone to damage even after multi-time folding and expansion, is free of frequent replacement, and reduces apparatus maintenance cost. Since the stainless steel material has high resistivity relative to copper and aluminum materials, when the radio frequency current in the radio frequency circuit flows through the bellows prepared by the stainless steel, it is inevitable that the bellows generates heat, which will cause losses of the radio frequency current. The conductive connector 190 reduces the radio frequency current required to be borne by the bellows prepared by the stainless steel, which shares the “radio frequency current pressure” of the bellows, which makes heating of the bellows within an acceptable range, and reduces losses of the radio frequency current by the bellows. By the actual test, due to the conductive connectors 190, temperature rise of the bellows prepared by the stainless steel material is little and controllable.

It is to be understood that a length of the conductive connectors 190 is greater than or equal to a maximum height of the retractable sealing assembly 180. When the movable lower electrode assembly 110 moves up and down, the stretching and compression state of the retractable sealing assembly 180 changes accordingly. Under normal conditions, the up-down movement distance of the movable lower electrode assembly 110 is within the maximum height range of the retractable sealing assembly 180, and the length of the conductive connectors 190 is greater than or equal to the maximum height of the retractable sealing assembly 180, which can guarantee that the up-down movement of the movable lower electrode assembly 110 cannot be limited by the length of the conductive connectors 190 and cannot influence connection of the conductive connectors 190, thereby guaranteeing the stability of the radio frequency circuit.

Further, the conductivity of the conductive connector 190 is greater than that of the retractable sealing assembly 180. In the embodiment, the conductive connector 190 and the retractable sealing assembly 180 are both located in the radio frequency circuit, and when the conductivity of the conductive connector 190 is higher, the radio frequency current preferably flows along a path with low impedance, and most of the radio frequency current is distributed to the conductive connector 190, thereby further reducing the radio frequency power pressure required to be borne by the retractable sealing assembly 180, contributing to prolonging the service life of the retractable sealing assembly 180, reducing object and manpower consumption, and meanwhile further guaranteeing stability of a vacuum degree of the sealing space in the vacuum processing chamber 100.

Optionally, two ends of the conductive connector 190 are directly electrically connected to the movable grounding ring 150 and the fixed grounding ring 160 (please refer to FIG. 2), and accordingly, the radio frequency path is formed between the movable grounding ring 150 and the fixed grounding ring 160. Of course, the conductive connector 190 may also adopt another connection manner which is not limited by the present disclosure, as long as the radio frequency path can be formed between the movable grounding ring 150 and the fixed grounding ring 160, by the conductive connector 190.

Preferably, in the embodiment, a top and a bottom of the conductive connector 190 are electrically connected to a top and a bottom of the retractable sealing assembly 180 respectively, that is, the conductive connector 190 and the retractable sealing assembly 180 may be regarded as an integral assembly (please refer to FIG. 1). If the conductive connector 190 is far away from the retractable sealing assembly 180, there are two paths to be selected when the radio frequency current in the radio frequency circuit is transferred from the fixed grounding ring 160 to the retractable sealing assembly 180: 1) the radio frequency current is transferred to the movable grounding ring 150 from the outer side of the retractable sealing assembly 180; and 2) the radio frequency current flows to the outer side of the conductive connector 190 from the bottom of the retractable sealing assembly 180, and then is transferred, through a top of the outer side of the conductive connector 190 and the bottom of the movable grounding ring 150, to a top of the inner side of the retractable sealing assembly 180 and the outer side of the movable grounding ring 150, that is, a small radio frequency circuit is formed between the conductive connector 190 and the retractable sealing assembly 180. When the retractable sealing assembly 180 is compressed or stretched along with ascending and descending of the movable lower electrode assembly 110, impedance of each circuit changes, and as a result, the whole radio frequency electric field is instable. In a similar way, there may also be two paths to be selected when the radio frequency current flows to the outer side of the conductive connector 190 from the movable grounding ring 150, which is likely to cause the problem about radio frequency instability. In the embodiment, the conductive connector 190 and the retractable sealing assembly 180 are connected and have no distance difference therebetween in the horizontal direction. When the radio frequency current is transferred, no matter how the retractable sealing assembly 180 is compressed or stretched, an impedance difference between the retractable sealing assembly 180 and the conductive connector 190 is very small, and no additional radio frequency circuit is generated therebetween, thereby further guaranteeing the stability of the integral radio frequency circuit and contributing to improving the stability of the etching rate.

In the embodiment, two end parts of the retractable sealing assembly 180 are fixed to the movable grounding ring 150 or the fixed grounding ring 160 through flange assemblies so that the sealing space of the vacuum processing chamber 100 can be jointly surrounded by the side wall of the vacuum processing chamber 100, the movable lower electrode assembly 110, the movable grounding ring 150, the retractable sealing assembly 180 and the fixed grounding ring 160.

Further, positions where the flange assemblies are in contact with the movable grounding ring 150 or the fixed grounding ring 160 are provided with a plurality of sealing members. The flange assemblies and the sealing members are combined, thereby guaranteeing tight connection between the retractable sealing assembly 180 and the movable grounding ring 150 or the fixed grounding ring 160, also guaranteeing airtightness of the closed space formed in the vacuum processing chamber 100, and guaranteeing the wafer production environment. Optionally, the sealing members are rubber O-shaped rings with certain toughness, and thus mechanical abrasion caused to the flange assemblies or the movable grounding ring 150 or the fixed grounding ring 160 is avoided.

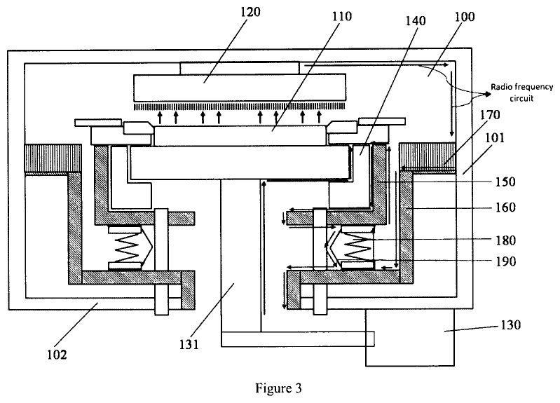

In the embodiment, the conductive connector 190 is a conductor (please refer to FIG. 1). Optionally, the conductor is a copper conductor. Of course, the conductive connector 190 is not only limited to the foregoing type and material, but also may be other types of conductive elements, which is not limited by the present disclosure. As shown in FIG. 3, in another embodiment, the conductive connector 190 is flexible metal sheet with mechanical strength slightly higher than that of the conductor type conductive connector 190, and meanwhile the conductivity and usability of the flexible metal sheet cannot be influenced even after multi-time folding along with multi-time ascending and descending of the movable lower electrode assembly 110. Further, the flexible metal sheet is bent metal sheet, the bent metal sheet is easy to fold along an original fold during stretching and compression, and the bending direction is easier to control. Optionally, the bending direction of the bent metal sheet may be towards a chamber body center of the vacuum processing chamber 100. When the movable lower electrode assembly 110 moves up and down along with the RF rod 131, the flexible metal sheet is bent towards the side away from the retractable sealing assembly 180 without contact with the retractable sealing assembly 180, thereby avoiding influences on stretching and compression of the retractable sealing assembly 180, and meanwhile avoiding damage to the retractable sealing assembly 180 by the flexible metal sheet along with multi-time ascending and descending of the movable lower electrode assembly 110. Optionally, the flexible metal sheet is flexible copper sheet, and of course, may be prepared by other conductive metal materials.

Optionally, a plurality of conductive connectors 190 are arranged between the movable grounding ring 150 and the fixed grounding ring 160, and the conductive connectors 190 are symmetrically arranged relative to a central axis of the movable lower electrode assembly 110, that is, the conductive connectors 190 symmetrically encircle the RF rod 131, so that the radio frequency circuit of the plasma processing device is symmetrically distributed, thereby contributing to improving the uniform radio frequency field formed in the sealing space of the vacuum processing chamber 100 so as to disintegrate the process gas to form a uniform plasma reaction field, contributing to improving wafer processing uniformity, and improving the wafer production yield.

In conclusion, the plasma processing device according to the present disclosure combines the movable grounding ring 150, the fixed grounding ring 160, the retractable sealing assembly 180 with the conductive connector 190, etc., which eliminates the unexpected radio frequency in the radio frequency circuit, which coupled to the retractable sealing assembly 180. The conductive connector 190 shares the radio frequency current bearing pressure of the retractable sealing assembly 180, and meanwhile, the retractable sealing assembly 180 is far away from the vertical part of the fixed grounding ring 160, thereby weakening horizontal-direction radio frequency coupling of the vertical part of the fixed grounding ring 160 to the retractable sealing assembly 180, and even when the retractable sealing assembly 180 is stretched or compressed, the radio frequency circuit cannot be greatly influenced.

Further, the retractable sealing assembly 180 in the device is electrically connected to the movable grounding ring 150 and the fixed grounding ring 160, so that vertical-direction radio frequency coupling caused by the movable grounding ring 150 and the fixed grounding ring 160 to the retractable sealing assembly 180 is eliminated; and meanwhile, the retractable sealing assembly 180 and the conductive connector 190 jointly share the radio frequency current, and thus, the radio frequency pressure required to be borne by the retractable sealing assembly 180 and the losses of the retractable sealing assembly 180 are reduced, and the service life of the retractable sealing assembly 180 is prolonged.

Further, the top and the bottom of the conductive connector 190 in the device are electrically connected to the top and the bottom of the retractable sealing assembly 180 respectively, and there is no distance difference therebetween in the horizontal direction. When the radio frequency current is transferred, no matter how the retractable sealing assembly 180 is stretched or compressed, the impedance difference between the retractable sealing assembly 180 and the conductive connector 190 is very small, and no additional radio frequency circuit is generated therebetween, thereby further guaranteeing the stability of the integral radio frequency circuit, contributing to improving the stability of the etching rate, and then, guaranteeing the wafer production yield.

It is to be explained that in the embodiments of the present disclosure, orientation or position relationships indicated by terms “center”, “longitudinal”, “transverse”, “upper”, “lower”, “vertical”, “horizontal”, “top”, “bottom”, “inner side”, “outer side”, “radial direction”, “circumferential direction” and the like are orientation or position relationships shown based on the drawings, are adopted not to indicate or imply that indicated devices or components must be in specific orientations or structured and operated in specific orientations but only to conveniently describe the embodiments, and thus should not be understood as limits to the present disclosure.

Although the content of the present disclosure has been introduced in detail through the above preferred embodiments, it is to be realized that the above description should not be understood as limits to the present disclosure. After those skilled in the art reads the above content, many modifications and substitutions made to the present disclosure are apparent. Therefore, the scope of protection of the present disclosure should be limited by the attached claims.

1. A plasma processing device, comprising:
a vacuum processing chamber internally provided with a movable lower electrode assembly;
a movable grounding ring arranged at a bottom of the movable lower electrode assembly in an encircling manner;
a fixed grounding ring arranged below the movable grounding ring in an encircling manner and in contact with a bottom of the vacuum processing chamber;
a retractable sealing assembly arranged between the movable grounding ring and the fixed grounding ring in an encircling manner;
a conductive connector used for forming a radio frequency path between the movable grounding ring and the fixed grounding ring, wherein a distance between an outer wall of the retractable sealing assembly and a center axis of the vacuum processing chamber is less than an outer diameter of the movable grounding ring; and
a match fixed at the bottom of the vacuum processing chamber, wherein the match has a radio frequency transmitting end and a radio frequency receiving end of a radio frequency circuit.

2. The plasma processing device according to claim 1, wherein
the conductive connector is electrically connected to the movable grounding ring and the fixed grounding ring.

3. The plasma processing device according to claim 1, wherein
the conductive connector is arranged on the side of the retractable sealing assembly, which away from an inner side wall of the vacuum processing chamber.

4. The plasma processing device according to claim 3,
further comprising: an upper electrode assembly opposite to the movable lower electrode assembly; and
a RF rod with two ends connected to the movable lower electrode assembly and the radio frequency transmitting end of the match respectively;
wherein the vacuum processing chamber comprises a processing chamber side wall and a processing chamber bottom wall, and the retractable sealing assembly is electrically connected to the movable grounding ring and the fixed grounding ring; and
according to the radio frequency path of the plasma processing device, a radio frequency current output by the radio frequency transmitting end of the match enters the movable lower electrode assembly through the RF rod, enters the upper electrode assembly through plasma between the upper electrode assembly and the movable lower electrode assembly, and then is transmitted to the radio frequency receiving end of the match sequentially through the processing chamber side wall, an inner side of the fixed grounding ring, an outer side of the retractable sealing assembly, an outer side of the movable grounding ring, an inner side of the movable grounding ring, a bottom of the movable grounding ring, an inner side of the conductive connector, the inner side of the fixed grounding ring and the processing chamber bottom wall.

5. The plasma processing device according to claim 1, wherein
a length of the conductive connector is greater than or equal to a maximum height of the retractable sealing assembly.

6. The plasma processing device according to claim 1, wherein
the conductivity of the conductive connector is greater than that of the retractable sealing assembly.

7. The plasma processing device according to claim 1, wherein
the conductive connector is a conductor or flexible metal sheet.

8. The plasma processing device according to claim 7, wherein
the conductor is a copper conductor, and the flexible metal sheet is flexible copper sheet.

9. The plasma processing device according to claim 7, wherein
the flexible metal sheet is bent metal sheet with a bending direction towards a chamber body center of the vacuum processing chamber.

10. The plasma processing device according to claim 1, wherein
a plurality of the conductive connectors are arranged and symmetrically arranged relative to a central axis of the movable lower electrode assembly.

11. The plasma processing device according to claim 1, wherein
a prepared material of the retractable sealing assembly is stainless steel.

12. The plasma processing device according to claim 1, wherein
the retractable sealing assembly comprises a bellows.

13. The plasma processing device according to claim 1, wherein
a top and a bottom of the conductive connector are electrically connected to a top and a bottom of the retractable sealing assembly respectively.

14. The plasma processing device according to claim 13, wherein
end parts of the retractable sealing assembly are fixed to the movable grounding ring and the fixed grounding ring through flange assemblies.

15. The plasma processing device according to claim 14, wherein
positions where the flange assemblies are in contact with the movable grounding ring or the fixed grounding ring are provided with a plurality of sealing members.

16. The plasma processing device according to claim 13, wherein
the conductive connector is arranged on the side of the retractable sealing assembly, which close to an inner side wall of the vacuum processing chamber, and the conductive connector is prepared by materials not reacting with process gas or byproducts in the vacuum processing chamber thereof.

17. The plasma processing device according to claim 1, wherein there is one or more matches, and the plurality of matches are different in radio frequency and power.

18. The plasma processing device according to claim 1, wherein end parts of the retractable sealing assembly are fixed to the movable grounding ring and the fixed grounding ring through flange assemblies.

19. The plasma processing device according to claim 17, wherein
positions where the flange assemblies are in contact with the movable grounding ring or the fixed grounding ring are provided with a plurality of sealing members.

20. The plasma processing device according to claim 2, wherein
the conductive connector is arranged on the side of the retractable sealing assembly, which close to an inner side wall of the vacuum processing chamber, and the conductive connector is prepared by materials not reacting with process gas or byproducts in the vacuum processing chamber thereof.
